(19) United States
(12) Patent Application Publication
(10) Pub. No.: US 2015/0187678 A1
(43) Pub. Date: Jul. 2, 2015

(54) POWER SEMICONDUCTOR DEVICE

(71) Applicant: Samsung Electro-Mechanics Co., Ltd., Suwon-Si (KR)

(72) Inventors: Jae Hoon PARK, Suwon-Si (KR); Sun Jae Yoon, Suwon-Si (KR); Chang Su Jang, Suwon-Si (KR); Kee Ju Um, Suwon-Si (KR); In Hyuk Song, Suwon-Si (KR)

(73) Assignee: Samsung Electro-Mechanics Co., Ltd., Suwon-Si (KR)

(21) Appl. No.: 14/270,894

(22) Filed: May 6, 2014

(30) Foreign Application Priority Data
Dec. 27, 2013 (KR) 10-2013-0165240

(51) Int. Cl. H01L 23/373

(52) U.S. Cl. CPC H01L 23/3736; H01L 29/7393

(57) ABSTRACT

A power semiconductor device may include: a first conductivity-type first semiconductor layer; a second conductivity-type second semiconductor layer disposed above the first semiconductor layer; and a heat dissipation trench disposed to penetrate from an upper surface of the second semiconductor layer into a portion of the second semiconductor layer and having an insulating layer disposed on a surface thereof.

### CROSS-REFERENCE TO RELATED APPLICATION

This application claims the benefit of Korean Patent Application No. 10-2013-0165240 filed on Dec. 27, 2013, with the Korean Intellectual Property Office, the disclosure of which is incorporated herein by reference.

### BACKGROUND

The present disclosure relates to a power semiconductor device having excellent heat dissipation characteristics.

An insulated-gate bipolar transistor (IGBT) is a transistor with a gate manufactured by using a metal-oxide semiconductor (MOS) structure and forming a p-type collector layer on a rear surface thereof having bipolarity.

Since the development of conventional power Metal-Oxide Semiconductor Field Emission Transistors (MOSFET), such MOSFETs have been used in fields in which fast switching characteristics are required.

However, due to inherent structural limitations of MOSFETs, bipolar transistors, thyristors, gate turn-off thyristors (GTO), and the like, have been used in fields in which high voltage are required.

IGBTs, featuring low forward loss and fast switching speeds, tend to extendedly applied to applications in various fields for which existing thyristors, bipolar transistors, MOSFETs, and the like are unsuitable.

As for an operating principle of an IGBT, in the case that an IGBT device is turned on and a voltage higher than that of a cathode is applied to an anode, while a voltage higher than a threshold value of the device is applied to a gate electrode, a polarity of a surface of a p-type body region positioned in a lower end portion of the gate electrode is reversed to form an n-type channel.

An electron current injected into a drift region through the n-type channel induces injection of a hole current from a p-type collector layer having a high concentration positioned in a lower portion of the IGBT device, such as a base current of a bipolar transistor.

The injection of the minority carrier having a high concentration increases conductivity in the drift region by tens to hundreds of times (an order of magnitude of one or two), causing conductivity modulation.

Unlike a MOSFET, a resistance component in the drift region may be reduced in size to be significantly low due to the conductivity modulation, and thus, extremely high voltages may be applied to IGBT devices.

A current flowing to a cathode may be divided into an electron current, flowing through a channel, and a hole current, flowing through a junction between a p-type body and an n-type drift region.

An IGBT may have a PNP structure between an anode and a cathode in terms of a substrate structure, so unlike a MOSFET, a diode may not be installed, and thus, a separate diode may need to be connected to an IGBT through an inverse-parallel connection.

When an IGBT device operates, heat is inevitably generated.

Heat generated while an IGBT device is operated causes thermal runaway, as well as degrading electrical characteristics of the IGBT.

Thus, a scheme of dissipating heat generated within an IGBT device to the outside of the chip to enhance electrical characteristics of the IGBT and device stability is required.

### SUMMARY

An aspect of the present disclosure may provide a structure capable of outwardly dissipating heat generated within a power semiconductor device to enhance electrical characteristics and stability of the power semiconductor device.

According to an aspect of the present disclosure, a power semiconductor device may include: a first conductivity-type first semiconductor layer; a second conductivity-type second semiconductor layer disposed above the first semiconductor layer; and a heat dissipation trench disposed to penetrate from an upper surface of the second semiconductor layer to a portion of the second semiconductor layer and having an insulating layer disposed on a surface thereof.

The power semiconductor device may further include a thermally conductive material filling the heat dissipation trench.

The thermally conductive material may be at least one selected from the group consisting of Ag, Au, Cu, and Al, or a mixture thereof.

The power semiconductor device may further include a heat sink disposed above the second semiconductor layer such that the heat sink is exposed to the outside, and connected to the thermally conductive material to dissipate heat outwardly.

The heat dissipation trench may be disposed to penetrate through to a portion in which the first semiconductor layer and the second semiconductor layer are contiguous.

According to another aspect of the present disclosure, a power semiconductor device may include: a first conductivity-type first semiconductor layer; a second conductivity-type second semiconductor layer disposed above the first semiconductor layer; and a heat dissipation trench disposed to penetrate from a lower surface of the first semiconductor layer to a portion of the first semiconductor layer and having an insulating layer disposed on a surface thereof.

The power semiconductor device may further include a thermally conductive material filling the heat dissipation trench.

The thermally conductive material may be at least one selected from the group consisting of Ag, Au, Cu, and Al, or a mixture thereof.

The power semiconductor device may further include a heat sink disposed below the first semiconductor layer such that the heat sink is exposed to the outside, and connected to the thermally conductive material to dissipate heat outwardly

The heat dissipation trench may be disposed to penetrate through to a portion in which the first semiconductor layer and the second semiconductor layer are contiguous.

According to another aspect of the present disclosure, a power semiconductor device may include: a first conductivity-type first semiconductor layer; a second conductivity-type second semiconductor layer disposed above the first semiconductor layer; and a heat dissipation trench disposed to penetrate through the first semiconductor layer and the second semiconductor layer and having an insulating layer disposed on a surface thereof.

The power semiconductor device may further include a thermally conductive material filling the heat dissipation trench.

The power semiconductor device may further include a first heat sink disposed above the second semiconductor layer such that the first heat sink is exposed to the outside, and connected to the thermally conductive material to dissipate heat to the outside; and a second heat sink disposed below the first semiconductor layer such that the second heat sink is exposed to the outside, and connected to the thermally conductive material to dissipate heat to the outside.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically illustrating a power semiconductor device according to an exemplary embodiment of the present disclosure;

FIG. 2 is a cross-sectional view schematically illustrating a power semiconductor device in which a heat dissipation trench is formed to penetrate through to a portion in which a body layer and a drift layer are contiguous according to an exemplary embodiment of the present disclosure;

FIG. 3 is a cross-sectional view schematically illustrating a power semiconductor device including a heat sink formed therein according to an exemplary embodiment of the present disclosure;

FIG. 4 is a cross-sectional view schematically illustrating a power semiconductor device according to another exemplary embodiment of the present disclosure;

FIG. 5 is a cross-sectional view schematically illustrating a power semiconductor device in which a heat dissipation trench is formed to penetrate through to a portion in which a body layer and a drift layer are contiguous according to another exemplary embodiment of the present disclosure;

FIG. 6 is a cross-sectional view schematically illustrating a power semiconductor device including a heat sink formed therein according to another exemplary embodiment of the present disclosure;

FIG. 7 is a cross-sectional view schematically illustrating a power semiconductor device including a heat sink formed therein according to another exemplary embodiment of the present disclosure; and

FIG. 8 is a cross-sectional view schematically illustrating a power semiconductor device including a heat sink formed therein according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

A power switch may be implemented by any one of a power metal-oxide semiconductor field emission transistor (MOSFET), an insulated-gate bipolar transistor (IGBT), various types of thyristor, or the like. Most new techniques disclosed herein will be described based on IGBTs. However, various exemplary embodiments disclosed herein are not limited to IGBTs and may be applied to any type of power switch technique, including power MOSFETs and various types of thyristors, besides IGBTs. In addition, various exemplary embodiments of the present disclosure are described to include particular p-type and n-type regions. However, obviously, the exemplary embodiments described herein may also be applied to devices including regions having opposite conductivity types in the same manner.

Also, as used herein, p-type and n-type may be defined as a first conductivity-type or a second conductivity-type. Meanwhile, first and second conductivity-types refer to different conductivity-types.

Also, in general, positive (+) refers to an element doped at a high concentration and negative (−) refers to an element state doped at a low concentration.

Hereinafter, for clarification, a first conductivity-type will be referred to as an n-type, while a second conductivity-type will be referred to as a p-type, but the present disclosure is not limited thereto.

Also, for clarification, a first semiconductor layer will be referred to as a drift layer and a second semiconductor layer will be referred to as a body layer, but the present disclosure is not limited thereto.

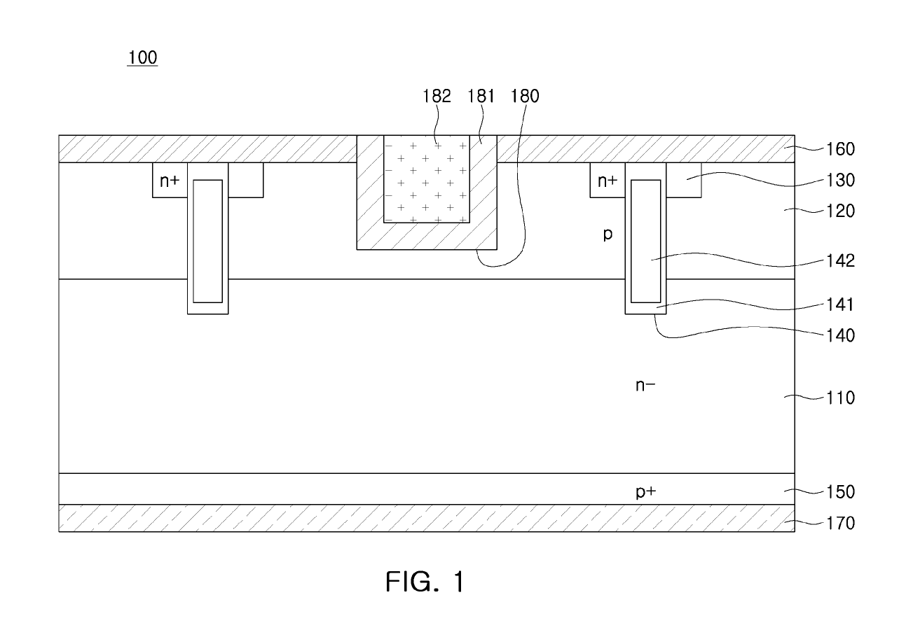

FIG. 1 is a cross-sectional view schematically illustrating a power semiconductor device 100 according to an exemplary embodiment of the present disclosure.

A structure of the power semiconductor device 100 according to an exemplary embodiment of the present disclosure will be described with reference to FIG. 1. The power semiconductor device 100 according to an exemplary embodiment of the present disclosure may include a drift layer 110, a body layer 120, an emitter region 130, a collector region 150, a trench gate 140, and a heat dissipation trench 180.

The drift layer 110 may be formed by injecting an n-type impurity having a low concentration.

Thus, in order to maintain a blocking voltage of the device, the drift layer 110 has a relatively large thickness.

The drift layer 110 may include a buffer region (not show) in a low portion thereof.

The buffer region (not shown) may be formed by injecting an n-type impurity into a rear surface of the drift layer 110.

The buffer region (not shown) may serve to hinder expansion of a depletion region of the device, helping to maintain a blocking voltage of the device.

Thus, in the case that the buffer region (not shown) is formed, the drift layer 110 may be formed to be thinner, reducing the size of the power semiconductor device.

The body layer 120 may be formed by injecting a p-type impurity to an upper surface of the drift layer 110.

The body layer 120 may have p-type conductivity, forming a p-n junction with the drift layer 110.

The emitter region 130 may be formed by injecting an n-type impurity having a high concentration into the interior of the upper surface of the body layer 120.

A trench gate 140 may be formed to penetrate from the emitter region 130, through the body layer 120, into a portion of the drift layer 110.

Namely, the trench gate 140 may be formed to penetrate from the emitter region 130 into a portion of the drift layer 110.

The trench gate 140 may be formed extendedly in one direction and may be arranged at a predetermined interval in a direction perpendicular to the direction in which the trench gates 140 are formed extendedly.

A gate insulating layer 141 may be formed in a portion where the trench gate 140 is in contact with the drift layer 110, the body layer 120, and the emitter region 130.

The gate insulating layer 141 may be formed of silicon oxide (SiO₂), but the present disclosure is not limited thereto.

The interior of the trench gate 140 may be filled with a conductive material 142.

The conductive material 142 may be polysilicon (Poly-Si) or a metal, but the present disclosure is not limited thereto.

The conductive material 142 is electrically connected to a gate electrode (not shown) to control an operation of the power semiconductor device 100 according to the exemplary embodiment of the present disclosure.

When a positive (+) voltage is applied to the conductive material 142, a channel C is formed in the body layer 120.

In detail, when a positive (+) voltage is applied to the conductive material 142, electrons present in the body layer 120 are attracted toward the trench gate 140, so electrons gathering at the trench gate 140 form a channel.

Namely, the trench gate 140 attracts electrons to form a channel in a depletion region with no carriers due to electron-hole recombination occurring at a p-n junction, allowing a current to flow.

The heat dissipation trench 180 may be formed to penetrate from an upper surface of the body layer 120 into a portion of the body layer 120.

An insulating layer 181 may be formed on a surface of the heat dissipation trench 180.

The insulating layer 181 may be formed by etching a portion of the body layer 120 and heat-treating the same under an oxygen atmosphere, when the heat dissipation trench 180 is formed. The insulating layer 181 may be formed of a silicon oxide (SiO₂) thin film, but the present disclosure is not limited thereto.

In order to increase heat dissipation characteristics, the insulating layer 181 may be formed of an epoxy having high heat conductivity, but the present disclosure is not limited thereto.

The interior of the heat dissipation trench 180 may be filled with a thermally conductive material 182 having excellent thermal conductivity.

The thermally conductive material 182 may be at least one selected from the group consisting of Ag, Au, Cu, and Al, or a mixture thereof.

The heat dissipation trench 180 may be formed to extend in one direction or be formed as an island.

Since the heat dissipation trench 180 is formed, heat generated within the power semiconductor device 100 may be released to the outside through the heat dissipation trench 180.

Thus, since heat of the power semiconductor device 100 is released outwardly through the heat dissipation trench 180, electrical characteristics of the power semiconductor device 100 may be enhanced.

Also, the occurrence of thermal runaway in the power semiconductor device 100 may be prevented.

Thermal runway refers to degradation of or damage to characteristics of a transistor due to heat, and as a temperature is increased, resistance of an element of an IGBT is lowered to increase a current, and the increase in current causes a temperature to be increased again to damage the power semiconductor device 100.

The power semiconductor device 100 according to the exemplary embodiment of the present disclosure may rapidly dissipate heat through the heat dissipation trench 180, reducing a possibility of generating thermal runaway, thus enhancing stability of the power semiconductor device 100.

The collector region 150 may be formed by injecting a p-type impurity into a lower surface of the drift layer 110.

In a case in which the power semiconductor device is an insulated-gate bipolar transistor (IGBT), the collector region 150 may provide holes to the power semiconductor device 100.

The injection of holes, minority carriers, having a high concentration causes conductivity modulation that conductivity is increased by tens to hundreds of times in the drift layer 110.

In particular, in a case in which a hole accumulation layer having an n-type impurity concentration higher than that of the drift layer 110 is formed between the drift layer 110 and the body layer 120, the hole accumulation layer may greatly increase an amount of accumulated holes, maximizing conductivity modulation to reduce loss during an ON operation of the power semiconductor device 100.

In a case in which the power semiconductor device is a metal-oxide semiconductor field emission transistor (MOSFET), the collector region 150 may have n-type conductivity.

An emitter metal layer 160 may be formed on the emitter region 130 and an exposed upper surface of the body layer 120, and a collector metal layer 170 may be formed on a lower surface of the collector region 150.

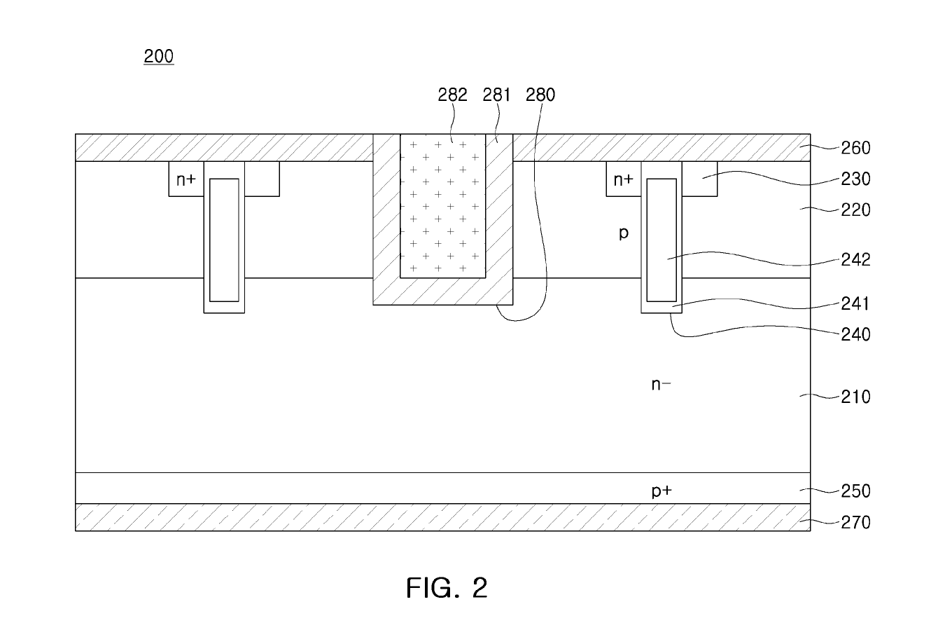

FIG. 2 is a cross-sectional view schematically illustrating a power semiconductor device 200 in which a heat dissipation trench 280 is formed to penetrate through into a portion in which a body layer 220 and a drift layer 210 are contiguous according to an exemplary embodiment of the present disclosure.

In the case that the power semiconductor device 200 is conducted to allow a current to flow therein, a largest amount of heat is generated in a region in which the drift layer 210 and the body layer 220 are contiguous, namely, a region in which a p-n junction is formed.

As illustrated in FIG. 2, in a case in which a heat dissipation trench 280 is formed to penetrate through into a portion in which the drift layer 210 and the body layer 220 are contiguous, heat generated from the portion in which the drift layer 210 and the body layer 220 are contiguous may be effectively removed.

Thus, in the case in which the heat dissipation trench 280 is formed to penetrate through up to a portion in which the drift layer 210 and the body layer 220 are contiguous, electrical characteristics of the power semiconductor device 200 may be enhanced, and since thermal runaway is prevented, stability of the power semiconductor device 200 may be enhanced.

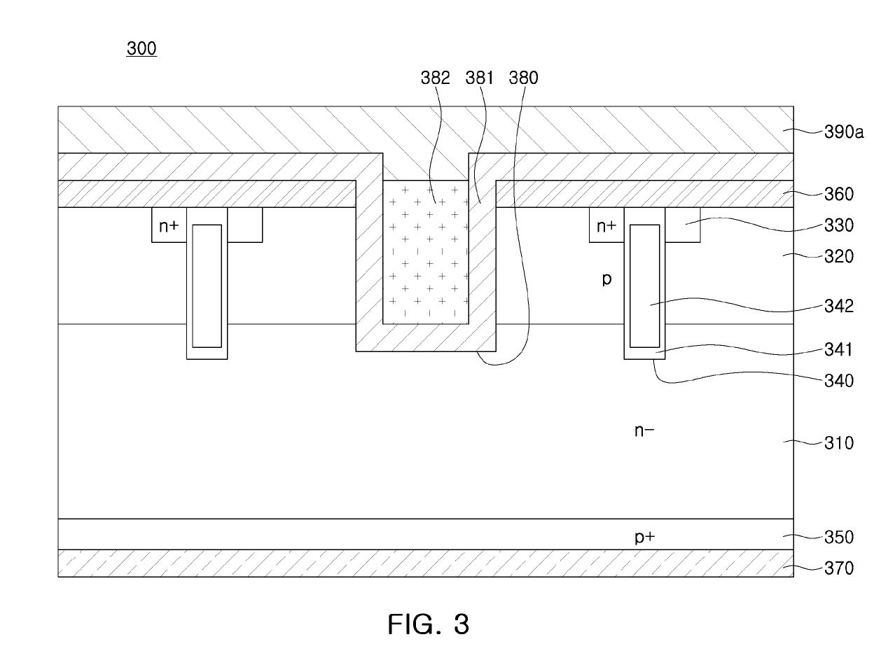

FIG. 3 is a cross-sectional view schematically illustrating a power semiconductor device 300 including a heat sink 390a formed therein according to an exemplary embodiment of the present disclosure.

As illustrated in FIG. 3, a heat dissipation trench 380 may be formed to be connected to a heat sink 390a.

The heat sink 390a may be formed above an emitter metal layer 360, and an insulating layer may be interposed between the emitter metal layer 360 and the heat sink 390a to insulate the heat sink 390a and the emitter metal layer 360.

The heat sink 390a may have a structure capable of rapidly dissipating heat transmitted from the heat dissipation trench 380 to the outside.

Thus, in the case of forming the heat sink 390a, electrical characteristics of the power semiconductor device 300 may be enhanced, and since thermal runaway is prevented, stability of the power semiconductor device 300 may be enhanced.

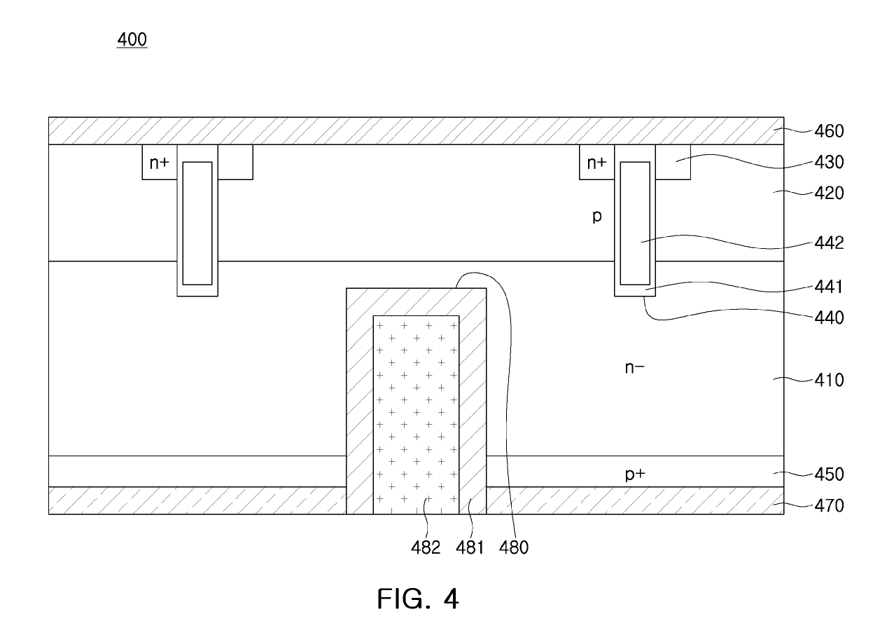

FIG. 4 is a cross-sectional view schematically illustrating a power semiconductor device 400 according to another exemplary embodiment of the present disclosure.

A structure of a power semiconductor device 400 according to another exemplary embodiment of the present disclosure will be described with reference to FIG. 4. The power semiconductor device 400 according to another exemplary embodiment of the present disclosure may include a first conductivity-type drift layer 410, a second conductivity-type body layer 420 formed above the first conductivity-type drift layer 410, and a heat dissipation trench 480 formed to penetrate from a lower surface of the drift layer 410 into a portion of the drift layer 410 and having an insulating layer 481 formed thereon.

The heat dissipation trench 480 may be formed by etching a portion of the lower surface of the drift layer 410.

If the heat dissipation trench 480 is formed on an upper surface of the power semiconductor device 400, a region in which a current flows may be reduced, which degrade performance of the power semiconductor device 400.

However, in the power semiconductor device 400 according to the present exemplary embodiment, since the heat dissipation trench 480 is formed on the lower surface, heat dissipation characteristics of the power semiconductor device 400 may be enhanced, without reducing a region in which a current flows.

Thus, since the occurrence of a phenomenon such as thermal runaway is prevented, without degrading electrical characteristics of the power semiconductor device 400, stability of the power semiconductor device 400 may be enhanced.

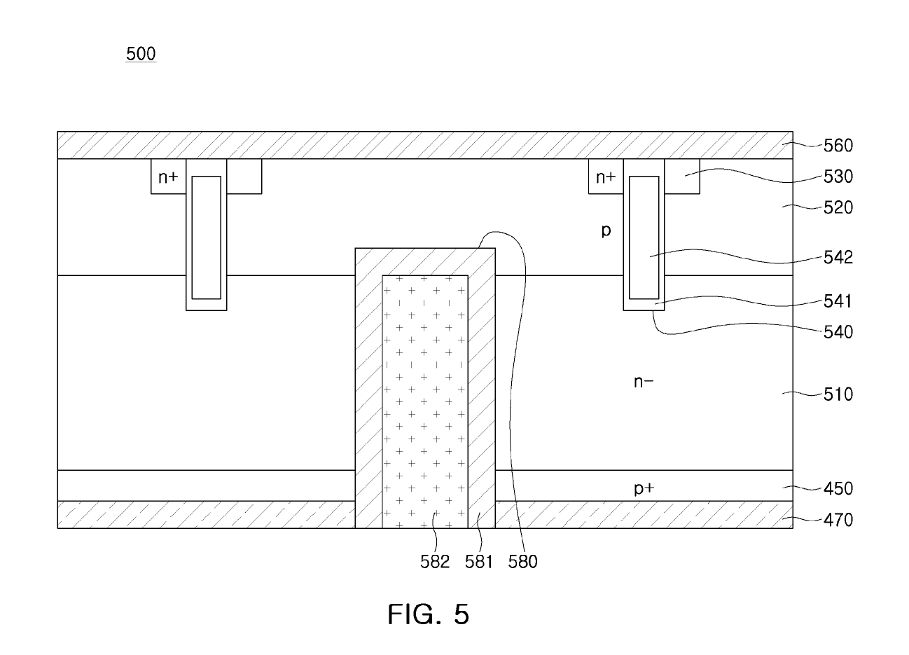

FIG. 5 is a cross-sectional view schematically illustrating a power semiconductor device 500 in which a heat dissipation trench 580 is formed to penetrate through up to a portion in which a body layer 520 and a drift layer 510 are contiguous according to another exemplary embodiment of the present disclosure.

In the cast that the power semiconductor device 500 is conducted to allow a current to flow therein, a largest amount of heat is generated in a region in which the drift layer 510 and the body layer 520 are contiguous, namely, a region in which a p-n junction is formed.

As illustrated in FIG. 5, in a case in which a heat dissipation trench 580 is formed to penetrate through into a portion in which the drift layer 510 and the body layer 520 are contiguous, heat generated from the portion in which the drift layer 510 and the body layer 520 are contiguous may be effectively removed.

Thus, in the case in which the heat dissipation trench 580 is formed to penetrate through to a portion in which the drift layer 510 and the body layer 520 are contiguous, electrical characteristics of the power semiconductor device 500 may be enhanced, and since thermal runaway is prevented, stability of the power semiconductor device 500 may be enhanced.

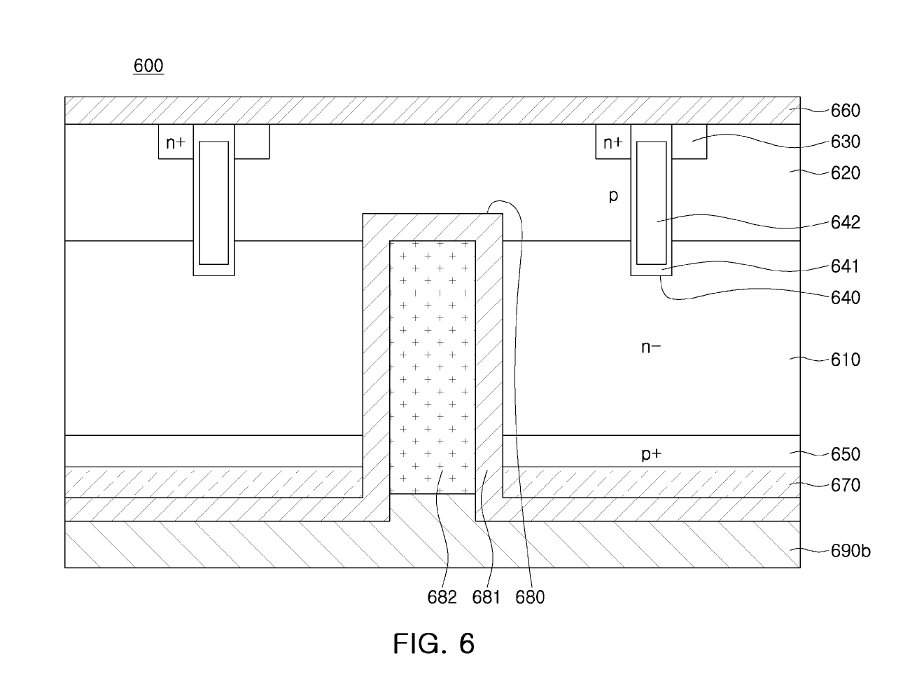

FIG. 6 is a cross-sectional view schematically illustrating a power semiconductor device 600 including a heat sink 690b formed therein according to another exemplary embodiment of the present disclosure.

As illustrated in FIG. 6, a heat dissipation trench 680 may be formed to be connected to a heat sink 690b.

The heat sink 690b may be formed below a collector metal layer 670, and an insulating layer may be interposed between the collector metal layer 670 and the heat sink 690b to insulate the heat sink 690b and the collector metal layer 670.

The heat sink 690b may have a structure capable of rapidly dissipating heat transmitted from the heat dissipation trench 680 to the outside.

Thus, in the case of forming the heat sink 690b, electrical characteristics of the power semiconductor device 600 may be enhanced, and since thermal runaway is prevented, stability of the power semiconductor device 600 may be enhanced.

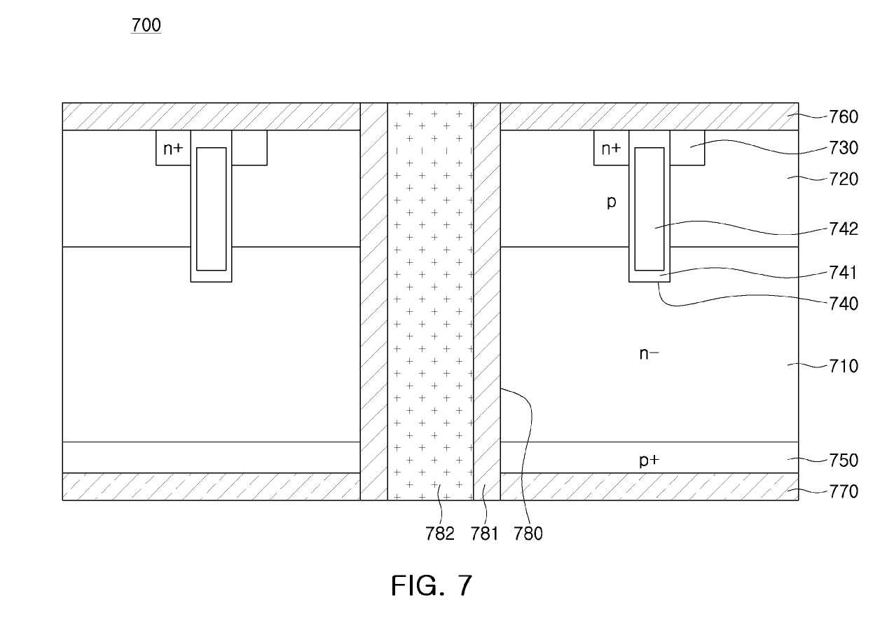

FIG. 7 is a cross-sectional view schematically illustrating a power semiconductor device 700 according to another exemplary embodiment of the present disclosure.

The power semiconductor device 700 according to another exemplary embodiment of the present disclosure may include a first conductivity-type drift layer 710, a second conductivity-type body layer 720 formed above the drift layer 710, and a heat dissipation trench 780 formed to penetrate through the drift layer 710 and the body layer 720 and having an insulating layer 481 formed thereon.

Since the heat dissipation trench 780 is formed to penetrate through the power semiconductor device 700, heat may be dissipated to both sides of the power semiconductor device 700.

Thus, electrical characteristics of the power semiconductor device 700 may be enhanced, and since a thermal runaway phenomenon is prevented, stability of the power semiconductor device 700 may be enhanced.

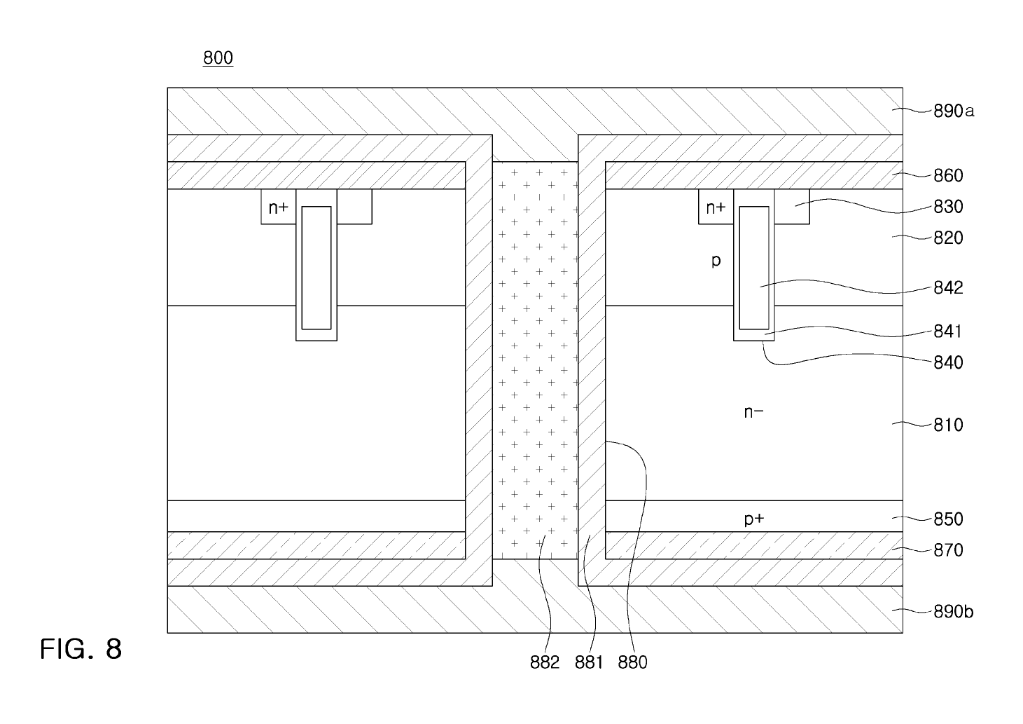

FIG. 8 is a cross-sectional view schematically illustrating a power semiconductor device 800 including a heat sink formed therein according to another exemplary embodiment of the present disclosure.

Referring to FIG. 8, a first heat sink 890a is formed above a body layer 820 and exposed to the outside, and a second heat sink 890b may be formed below a first semiconductor layer and exposed to the outside.

The first heat sink 890a and the second heat sink 890b may be connected to a thermally conductive material 882 to dissipate heat generated in the power semiconductor device 800 outwardly.

Thus, in the case of forming the first and second heat sinks 890a and 890b, electrical characteristics of the power semiconductor device 800 may be enhanced, and since a thermal runaway phenomenon is prevented, stability of the power semiconductor device 800 may be enhanced.

As set forth above, in a power semiconductor device according to exemplary embodiments of the present disclosure, by forming a heat dissipation trench formed to be penetrate from an upper surface of a body layer into a portion of a body layer or to a portion of a drift layer, a path for dissipating heat generated from the interior of the power semiconductor device outwardly may be provided.

Since heat generated within the power semiconductor device is dissipated outwardly, electrical characteristics of the power semiconductor device may be enhanced, and since occurrence of a phenomenon such as thermal runaway is prevented, stability of the power semiconductor device may be enhanced.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
a first conductivity-type first semiconductor layer;
a second conductivity-type second semiconductor layer disposed above the first semiconductor layer; and
a heat dissipation trench disposed to penetrate from an upper surface of the second semiconductor layer into a portion of the second semiconductor layer and having an insulating layer disposed on a surface thereof.

2. The power semiconductor device of claim 1, further comprising a thermally conductive material filling the heat dissipation trench.

3. The power semiconductor device of claim 2, wherein the thermally conductive material is at least one selected from the group consisting of Ag, Au, Cu, and Al, or a mixture thereof.

4. The power semiconductor device of claim 2, further comprising a heat sink disposed above the second semiconductor layer such that the heat sink is exposed to the outside, and connected to the thermally conductive material to dissipate heat outwardly.

5. The power semiconductor device of claim 1, wherein the heat dissipation trench is disposed to penetrate through into a portion in which the first semiconductor layer and the second semiconductor layer are contiguous.

6. A power semiconductor device comprising:
a first conductivity-type first semiconductor layer;
a second conductivity-type second semiconductor layer disposed above the first semiconductor layer; and
a heat dissipation trench disposed to penetrate from a lower surface of the first semiconductor layer into a portion of the first semiconductor layer and having an insulating layer disposed on a surface thereof.

7. The power semiconductor device of claim 6, further comprising a thermally conductive material filling the heat dissipation trench.

8. The power semiconductor device of claim 7, wherein the thermally conductive material is at least one selected from the group consisting of Ag, Au, Cu, and Al, or a mixture thereof.

9. The power semiconductor device of claim 7, further comprising a heat sink disposed below the first semiconductor layer such that the heat sink is exposed to the outside, and connected to the thermally conductive material to dissipate heat outwardly

10. The power semiconductor device of claim 6, wherein the heat dissipation trench is disposed to penetrate through into a portion in which the first semiconductor layer and the second semiconductor layer are contiguous.

11. A power semiconductor device comprising:
a first conductivity-type first semiconductor layer;
a second conductivity-type second semiconductor layer disposed above the first semiconductor layer; and
a heat dissipation trench disposed to penetrate through the first semiconductor layer and the second semiconductor layer and having an insulating layer disposed on a surface thereof.

12. The power semiconductor device of claim 11, further comprising a thermally conductive material filling the heat dissipation trench.

13. The power semiconductor device of claim 12, further comprising:
a first heat sink disposed above the second semiconductor layer such that the first heat sink is exposed to the outside, and connected to the thermally conductive material to dissipate heat to the outside; and
a second heat sink disposed below the first semiconductor layer such that the second heat sink is exposed to the outside, and connected to the thermally conductive material to dissipate heat to the outside.
